(19) United States
(12) Patent Application Publication
(10) Pub. No.: US 2008/0219023 A1
(43) Pub. Date: Sep. 11, 2008

(54) Printed circuit board for fitting with a punched grid

(76) Inventors: Manfred J. Groben, Gau-Bickelheim (DE); Peter Leng, Mainz (DE)

Correspondence Address: DELPHI TECHNOLOGIES, INC., M/C 480-410-202, PO BOX 5052, TROY, MI, 48007, US

(21) Appl. No.: 12/072,542

(22) Filed: Feb. 27, 2008

(30) Foreign Application Priority Data
Mar. 8, 2007 (EP) 07004735.2

(51) Int. Cl. F21V 8/00; H05K 1/18; H05K 7/20

(52) U.S. Cl. 362/558; 361/710; 174/260

(57) ABSTRACT

In a printed circuit board for fitting with a three-dimensionally shaped punched grid comprising a plurality of current paths partially encapsulated by plastic and at least one electric or electronic component the punched grid is of angular construction. In this case free end faces of the current paths of the punched grid extending over the legs make contact with the printed circuit board and between the current paths the component is arranged in a defined orientation.

### TECHNICAL FIELD

The invention relates to a printed circuit board for fitting with a three-dimensionally shaped punched grid comprising a plurality of current paths partially encapsulated in plastic and at least one electric or electronic component.

### BACKGROUND OF THE INVENTION

DE 38 21 121 A1 describes a method for producing a contact carrying member provided with electrically conductive connecting tracks and with rigid contact parts such as contact springs, light sockets and the like. First of all the rigid contact parts are fitted mechanically on the contact carrying board by insertion or clipping for which purpose mouldings or openings are arranged in the region of the fastening points and then a pasty or liquid contact compound is applied to form the electrically conducting connecting tracks. By means of the method described the disadvantageous use of printed circuit boards and punched grids is to be avoided.

Furthermore, DE 10 2005 006 819 A1 presents a printed circuit board with a light-emitting diode in SMD (surface mount device) technology whose connecting contacts are soldered on the upper side of the component. In order to allow dissipation of heat in the operation of the light-emitting diode the printed circuit board is provided with numerous feedthroughs in the region of the light-emitting diode. Problems arise when the component must point in a certain direction since in a directed application it is usually necessary to mount the printed circuit board in an appropriate installation position requiring a relatively large installation space. Furthermore, there is only limited heat dissipation from the light-emitting diode through the feedthroughs.

### SUMMARY OF THE INVENTION

It is an object of the invention to provide a printed circuit board of the type identified at the outset to which a component has to be fastened in a defined direction diverging from the surface of the printed circuit board and reliable heat dissipation is ensured.

This task is solved according to the invention in that the punched grid is of angular construction, wherein free end faces of the current paths of the punched grid extending over the legs make contact with the printed circuit board and the component is arranged between the current paths in a defined orientation.

Through the punched grid whose legs holding the component and making electric contact with it are spaced apart from the printed circuit board perfect heat dissipation from the component is ensured without the need for special thermal precautions being taken on the printed circuit board.

Furthermore, the angular, that is to say roof-shaped punched grid fixes the component in a defined position diverging from the surface of the printed circuit board. In this way space-saving assembly is possible.

Preferably at least one of the legs of the punched grid has a surface that is enlarged with respect to the other leg. The legs composed of metal serve with their current paths both as electric conductors and for conducting and transmitting heat. The relatively large leg of the punched grid gives rise to relatively speedy heat transfer.

The component making contact with the current paths is expediently a sensor, in particular a Hall sensor or a means of lighting. In order to focus emitted beams of light the means of lighting constructed as a light-emitting diode is preferably associated with a reflector arranged on the punched grid. Alternatively or in addition to the reflector the light-emitting diode is associated with a fibre optic light guide.

As a development the leg of the punched grid provided with the light-emitting diode is aligned parallel to a light emission surface of a diffuser disk of a light, in particular an interior light of a motor vehicle. Accordingly the light-emitting diode transmits radiation in the direction of the diffuser disk by means of which, for example, an accommodation space for the light-emitting diode is provided while the printed circuit board is to be accommodated in a relatively small housing. When used in an interior light in a motor vehicle which should emit light in the direction of a driver or passenger or towards the front and rear the printed circuit board may comprise two light-emitting diodes that are fastened to oppositely oriented legs of two punched grids arranged spaced apart from one another on the printed circuit board.

Expediently the punched grid and/or the component are constructed as a SMD component and the current paths of the punched grid make contact with the upper side of the printed circuit board. Accordingly, the printed circuit board is to be fitted with components closely spaced relative to one another and to be produced at low cost with a compact structure.

It is obvious that the characteristics identified above and still to be explained below are usable not only in the combination specified but also in other combinations. The scope of the invention is defined solely by the claims.

### BRIEF DESCRIPTION OF THE DRAWINGS

The invention is explained in more detail below on the basis of an exemplified embodiment with reference to the associated drawings.

These show:

FIG. 1 is a partial view in perspective of a printed circuit board according to the invention;

FIG. 2 is another partial view of the printed circuit board according to FIG. 1; and

FIG. 3 is an illustration of a layout of a punched grid according to the detail III in FIG. 1.

### DESCRIPTION OF THE PREFERRED EMBODIMENT

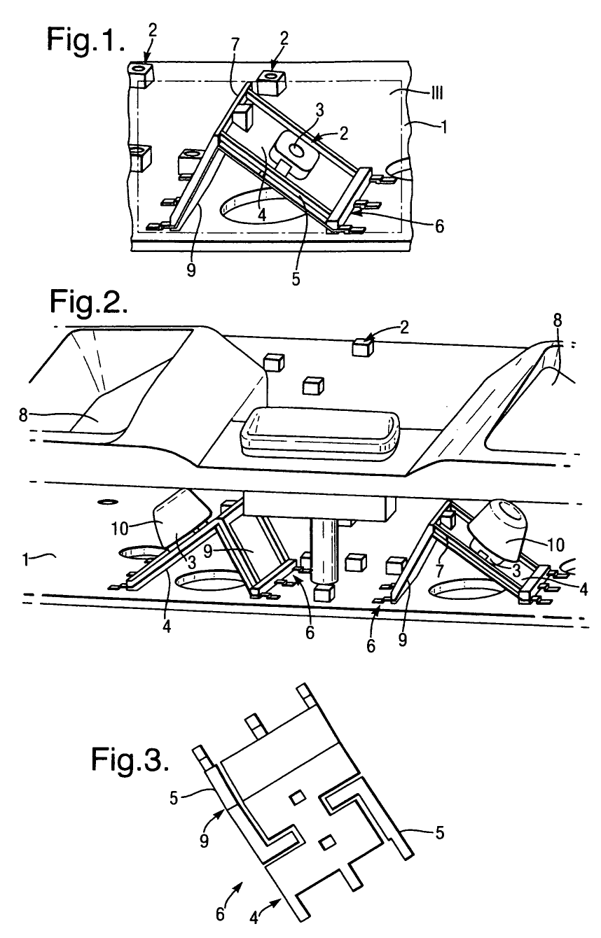

Referring to FIGS. 1-3, the printed circuit board 1 is part of an interior light in a motor vehicle and carries a plurality of electronic components 2 arranged in SMD technology of which two are constructed as light-emitting diodes 3. Each light-emitting diode 3 is fastened to a primary leg 4 of an angularly bent punched grid 6 comprising a plurality of current paths 5, wherein the current paths are embedded in a plastic 7 insulating the current paths 5 with respect to one another and at the free end faces of the punched grid 6 resting upon the printed circuit board 1 make electric contact with the printed circuit board 1. Due to the shape of the punched grid 6 the light-emitting diode 3 assumes a defined direction both with respect to the printed circuit board 1 and to a diffuser disk 8 of the interior light and it is possible by simple means to assign two light-emitting diodes 3 shining in different directions to a level printed circuit board 1. Furthermore, especially through the riser leg 9 not equipped with the light-emitting diode 3 which is designed to have greater area than the leg 4 carrying the light-emitting diode 3, the punched grid 6 ensures dissipation of the heat inevitably produced in the operation of the light-emitting diode 3. In order to bring about selective focusing of the light beam in the direction of the diffuser disk 8, the light-emitting diode 3 is associated with a reflector 10 fastened to the punched grid 6.

What is claimed is:

1. A printed circuit board assembly comprising a three-dimensionally shaped punched grid comprising a plurality of current paths partially encapsulated by plastic and at least one electric or electronic component, wherein the punched grid is of angular construction, wherein free end faces of the current paths of the punched grid extending over grid legs make contact with the printed circuit board and between the current paths the component is arranged in a defined orientation.

2. The printed circuit board assembly of claim 1, wherein at least one of the legs of the punched grid has an enlarged surface by comparison with the other legs.

3. The printed circuit board assembly of claim 1, wherein the component making contact with the current paths is a sensor, in particular a Hall sensor or a means of lighting.

4. The printed circuit board assembly of claim 1, further comprising a reflector arranged on the punched grid and cooperatively aligned with the means of lighting constructed as a light-emitting diode.

5. The printed circuit board assembly of claim 1, further comprising a fibre optic light guide assigned to the light-emitting diode.

6. The printed circuit board assembly of claim 1, wherein the leg of the punched grid provided with the light-emitting diode is aligned substantially parallel to a light emission surface of a diffuser disk of a light, in particular an interior light of a motor vehicle.

7. The printed circuit board assembly of claim 1, wherein the punched grid and/or the component are constructed as a SMD component and the current paths of the punched grid make contact with the upper side of the printed circuit board.

8. A leadframe assembly for power electronic devices adapted for mounting to a rigid, substantially planer substrate such as a printed circuit board, said lead frame assembly comprising:
a frame portion formed of electrically and thermally conductive material, and configured in a generally inverted v-shape;
a grid, punch-formed within said frame, defining a plurality of electrically isolated conductive traces and a mounting surface for supporting a power electronic device in an orientation spaced and angularly offset from an adjacent surface of an associated supporting substrate;
a support structure formed of electrically insulating material rigidly affixed to said frame; and
means operative to affect mechanical connection of said leadframe assembly and electrical connection of said conductive traces to said associated supporting substrate.

9. The leadframe assembly of claim 8, wherein said means affecting connection of the leadframe assembly to a substrate comprises a plurality of surface mounting pads integrally formed with and extending from said frame portion.

10. The leadframe assembly of claim 8, wherein edge surfaces of said frame portion are insert molded within said support structure.

11. The leadframe of assembly claim 8, wherein said frame portion functions as a heat sink for an associated power electronic device.

12. The leadframe assembly of claim 8, wherein said frame portion comprises a primary leg defining said mounting surface and the entirety of at least one of said conductive traces, and a riser leg defining at least a portion of at least one of said conductive traces.

13. The leadframe assembly of claim 12, wherein said primary and riser legs are integrally interconnected along a common frame portion hingeline.

14. The leadframe assembly of claim 8, wherein said conductive traces are laterally spaced to straddle said mounting surface.

15. The leadframe assembly of claim 8, wherein at least a portion of at least one of said conductive traces is insert molded within said support structure.
